(19) United States
(12) Patent Application Publication
(10) Pub. No.: US 2008/0160701 A1
(43) Pub. Date: Jul. 3, 2008

(54) Method of Fabricating Trench Gate Type MOSFET Device

(76) Inventor: HEE DAE KIM, Boocheon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/842,798

(22) Filed: Aug. 21, 2007

(30) Foreign Application Priority Data
Dec. 27, 2006 (KR) 10-2006-0134639

(51) Int. Cl. H01L 21/336

(52) U.S. Cl. 438/270; 257/E21.409

(57) ABSTRACT

Disclosed is a method of fabricating a trench gate type metal oxide semiconductor field-effect transistor (MOSFET) device. According to an embodiment, a trench can be formed in a semiconductor substrate. A gate oxide layer can be formed on an inner wall of the trench. A first insulating layer can be formed on the semiconductor substrate including the gate oxide layer. Polysilicon can be formed in the trench. A second insulating layer can be formed from the first insulating layer so as to be thinner than the first insulating layer by etching the first insulating layer to a determined thickness. A third insulating layer can be formed on the second insulating layer and the polysilicon. The third insulating layer can be etched to form spacers on sidewalls of the polysilicon. Then, the second insulating layer can be removed using the spacers as an etch mask.

### CROSS-REFERENCE TO RELATED APPLICATION

The present application claims the benefit under 35 U.S.C. § 119 of Korean Patent Application No. 10-2006-0134639, filed Dec. 27, 2006, which is hereby incorporated by reference in its entirety.

### BACKGROUND

In general, a power metal oxide semiconductor field-effect transistor (MOSFET) device has a very simple gate driving circuit due to high input impedance, and does not have time delay caused by storage or recombination of minority carriers when turned off. Thus, the power MOSFET device is broadly applied to applications such as a switching mode power supply, a lamp ballast, and a motor driving circuit.

A power MOSFET device typically employs the structure of a DMOSFET (Double-Diffused MOSFET) using a planar diffusion technique.

Recent studies have been made of the structure of a trench gate type MOSFET (UMOSFET) device, in which a semiconductor substrate is etched to a predetermined depth to form a trench, and the trench is filled with a gate conductive layer. This trench gate type MOSFET device increases the cell density per unit area, but decreases the resistance, so that it can obtain high integration and low source-to-drain on-state resistance (Rds(on)).

Because the trench gate type MOSFET device requires high driving voltage and high current density, the reliability is very important. Thus, when high bias voltage is applied for driving the device, the dielectric breakdown phenomenon of a trench gate oxide layer and leakage current characteristics are considerably important to the trench gate type MOSFET device.

FIGS. 1A, 1B and 1C show process views illustrating a method of fabricating a related trench gate type MOSFET device.

Referring to FIG. 1A, impurity of a second conductive type is selectively implanted into a semiconductor substrate 1 of a first conductive type, thereby forming a base region (not shown) of a second conductive type in the semiconductor substrate at a predetermined depth.

Subsequently, a high-concentration source region (not shown) of a first conductive type is formed on the base region, and a trench T passing through the source and base regions is formed.

Then, a gate oxide layer 2 is formed on an inner wall of the trench, and a hard mask oxide layer 3 is formed on the semiconductor substrate 1.

Polysilicon 4 is then deposited on the substrate 1 and completely fills the trench.

Referring to FIG. 1B, the polysilicon 4 is completely removed from any region other than the trench by performing dry etching. The polysilicon 4 is etched such that the polysilicon 4 fills the trench to half the height of the hard mask oxide layer 3, which is used as an etch stop layer.

Referring to FIG. 1C, the hard mask oxide layer 3 is removed using dry etching. In the dry etching process of removing the hard mask oxide layer 3, the trench gate oxide layer 2 is exposed to plasma, and thus suffers damage A. The damage to the trench gate oxide layer causes dielectric breakdown of the gate and leakage of electric current, and thus may cause fatal damage to reliability of the device.

### BRIEF SUMMARY

Accordingly, embodiments of the present invention are directed to a method of fabricating a trench gate type MOSFET device, in which a trench gate oxide layer is inhibited from being physically damaged, thereby improving dielectric breakdown and leakage current characteristics.

According to an embodiment, a method of fabricating a trench gate type metal oxide semiconductor field-effect transistor (MOSFET) device includes forming a trench in a semiconductor substrate; forming a gate oxide layer on an inner wall of the trench; forming a first insulating layer on the semiconductor substrate including the gate oxide layer; forming polysilicon in the trench; removing a portion of the first insulating layer so as to form a second insulating layer thinner than the first insulating layer; forming a third insulating layer on the second insulating layer including the polysilicon; etching the third insulating layer to form spacers on sidewalls of the polysilicon; and removing the second insulating layer.

### BRIEF DESCRIPTION OF THE DRAWINGS

FIGS. 1A, 1B and 1C show views illustrating a method of fabricating a related trench gate type MOSFET device.

FIGS. 2A through 2G show process views illustrating a method of fabricating a trench gate type MOSFET device according to an embodiment of the present invention.

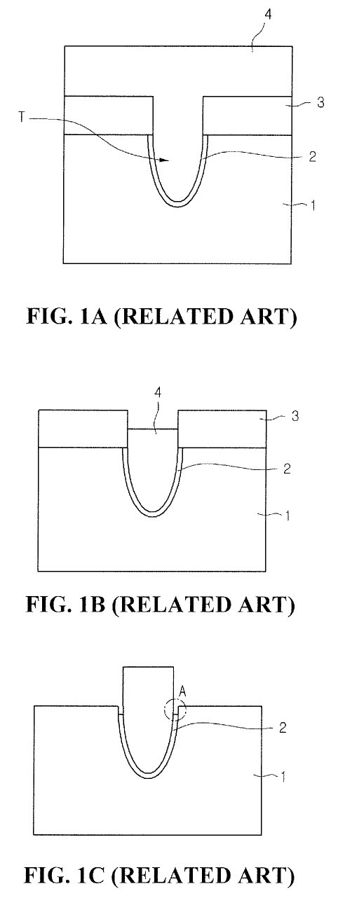

### DETAILED DESCRIPTION

Hereinafter, embodiments of the present invention will be described in detail with reference to the accompanying drawings. It will be understood that, when a layer (or film), a region, a pattern, or a structure is referred to as being “on (above/over/upper)” or “under (below/down/lower)” another substrate, another layer (or film), another region, another pad, or another pattern, it can be directly on the other substrate, layer (or film), region, pad, or pattern, or intervening layers may also be present. Furthermore, it will be understood that, when a layer (or film), a region, a pattern, a pad, or a structure is referred to as being “between” two layers (or films), regions, pads, or patterns, it can be the only layer between the two layers (or films), regions, pads, or patterns, or one or more intervening layers may also be present. Thus, it should be determined by technical idea of the invention.

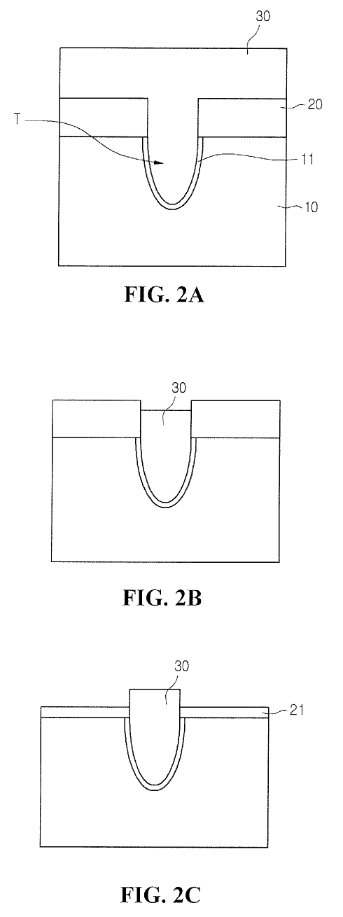

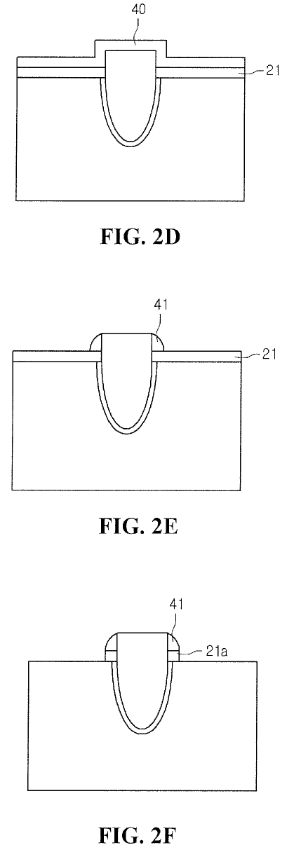

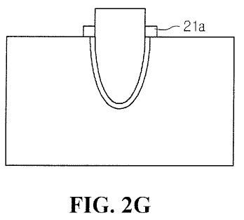

FIGS. 2A through 2G show process views illustrating a trench gate type MOSFET device according to an embodiment of the present invention.

Referring to FIG. 2A, impurity of a second conductive type can be selectively implanted into the semiconductor substrate 10 of a first conductive type to form a base region (not shown) of a second conductive type in the semiconductor substrate 10 at a predetermined depth.

Subsequently, a high-concentration source region (not shown) of a first conductive type is formed on the base region.

Then, a trench T passing through the source and base regions is formed, and a gate oxide layer 11 is formed on an inner wall of the trench.

A hard mask oxide layer 20 is formed on the semiconductor substrate 10. The hard mask oxide layer 20 is formed on the semiconductor substrate 10 and the gate oxide layer 11 excluding the trench T. The hard mask oxide layer 20 can be used as an etch stop layer in the following process.

According to embodiments, the hard mask oxide layer 20 and the gate oxide layer 11 can be formed of the same material.

Polysilicon 30 can be deposited on the substrate and in the trench T.

Referring to FIG. 2B, the polysilicon 30 is completely removed from any region other than the trench through, for example, dry etching using plasma.

The polysilicon 30 can be etched below the top surface of the hard mask oxide layer 20 used as the etch stop layer. For example, the polysilicon 30 can be etched down by tip to half the height of the mask oxide layer 20.

This is for preventing an excessive recession of the polysilicon during the dry etching.

Referring to FIG. 2C, the hard mask oxide layer 20 is partially removed by a predetermined thickness using dry etching, thereby forming a partial oxide layer 21.

The partial oxide layer 21 can be formed so as to be at least lower than the top surface of the polysilicon 30 filled in the trench T.

For example, the partial oxide layer 21 can be formed to have a thickness ranging from 30% to 70% of that of the hard mask oxide layer 20. In one embodiment, the partial oxide layer 21 can be formed to have a thickness of 50% of that of the hard mask oxide layer 20.

Referring to FIG. 2D, an insulating layer 40, which is formed of a material that is different from the hard mask oxide layer 20, is deposited on the partial oxide layer 21 and the polysilicon 30. For example, the insulating layer 40 can be made of nitride. Because a nitride layer is structurally denser than an oxide layer, the nitride may be preferred in certain embodiments.

Referring to FIG. 2E, the insulating layer 40 is etched to expose the top surface of the polysilicon 30 and form spacers 41 on sidewalls of the exposed polysilicon 30.

Referring to FIG. 2F, the partial oxide layer 21 can be removed. In one embodiment, the partial oxide layer 32 is removed from the surface of the substrate 10 by dry etching. At this time, partial regions 21a of the partial oxide layer 21 which are located under the spacers 41 are not removed.

Referring to FIG. 2G, the spacers 41 can be removed. In an embodiment, the spacers 41 are removed by wet etching using, for example, phosphoric acid.

Accordingly, a trench gate type MOSFET fabricated according to an embodiment of the present invention utilizes spacers on the sidewalls of the polysilicon before removing the hard mask oxide layer from the surface of the substrate to inhibit the gate oxide layer from being damaged.

Thus, the dielectric breakdown and leakage current characteristics of the trench gate type MOSFET can be improved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of fabricating a trench gate type metal oxide semiconductor field-effect transistor (MOSFET) device, the method comprising:
forming a trench in a semiconductor substrate;
forming a gate oxide layer on an inner wall of the trench;
forming a first insulating layer on the semiconductor substrate exposing the trench;
forming polysilicon in the trench;
removing a portion of the first insulating layer thereby forming a second insulating layer having a thickness thinner than the first insulating layer;
forming a third insulating layer on the second insulating layer and the polysilicon;
etching the third insulating layer to form spacers on sidewalls of the polysilicon; and
removing the second insulating layer.

2. The method according to claim 1, wherein forming polysilicon in the trench comprises:
depositing polysilicon on the semiconductor substrate including in the trench; and
removing the polysilicon from the top surface of the first insulating layer and a portion of the polysilicon in the trench to a height at least lower than the top surface of the first insulating layer.

3. The method according to claim 1, wherein removing a portion of the first insulating layer comprises etching the first insulating layer to a thickness corresponding to a range of 30% to 70% of the first insulating layer, thereby forming the second insulating layer having a thickness corresponding to the range of 30% to 70% of the first insulating layer.

4. The method according to claim 3, wherein the second insulating layer has a thickness corresponding to about 50% of the first insulating layer.

5. The method according to claim 1, wherein the first insulating layer comprises oxide.

6. The method according to claim 1, wherein the third insulating layer comprises nitride.

7. The method according to claim 1, wherein removing the second insulating layer comprises using the spacers as an etch mask such that the second insulating layer under the spacers is not removed.

8. The method according to claim 1, further comprising removing the spacers after removing the second insulating layer.

9. The method according to claim 8, wherein removing the spacers comprises performing wet etching.

10. The method according to claim 9, wherein performing wet etching comprises using phosphoric acid.
